(19) United States
(12) Patent Application Publication
(10) Pub. No.: US 2024/0087999 A1
(43) Pub. Date: Mar. 14, 2024

(54) PACKAGING SUBSTRATE HAVING METAL POSTS

(71) Applicant: SKYWORKS SOLUTIONS, INC., Irvine, CA (US)

(72) Inventors: Chien Jen WANG, Taoyuan City (TW); Ki Wook LEE, Irvine, CA (US); Yi LIU, San Diego, CA (US); Shaul BRANCHEVSKY, Mission Viejo, CA (US); Cai LIANG, Torrance, CA (US)

(21) Appl. No.: 18/464,182

(22) Filed: Sep. 8, 2023

Related U.S. Application Data
(60) Provisional application No. 63/405,819, filed on Sep. 12, 2022.

(51) Int. Cl. H01L 23/498; H01L 21/48; H05K 1/11

(52) U.S. Cl. CPC H01L 23/49811; H01L 21/4853; H05K 1/111; H01L 25/0655

(57) ABSTRACT

A packaging substrate assembly for fabricating a packaged module can include a packaging substrate having a surface, and an array of conductive pads implemented on the surface. The assembly can further include a conductive post formed over each conductive pad, with the conductive post including a first portion having a lateral dimension formed over the conductive pad and a second portion having a lateral dimension formed over the first portion. In some embodiments, the lateral dimension of the first portion is less than the lateral dimension of the second portion. In some embodiments, a dielectric layer can be implemented over the surface to cover the conductive pads and surround the first portion of each conductive post.

### CROSS-REFERENCE TO RELATED APPLICATION(S)

This application claims priority to U.S. Provisional Application No. 63/405,819 filed Sep. 12, 2022, entitled PACKAGING SUBSTRATE HAVING METAL POSTS, the disclosure of which is hereby expressly incorporated by reference herein in its entirety.

### BACKGROUND

### Field

The present disclosure relates to substrates for packaged electronic modules.

### Description of the Related Art

In many electronics applications, integrated circuits and/or circuit elements are implemented as parts of packaged modules. A packaged module typically includes a substrate configured to receive and support a plurality of components such as semiconductor die and/or circuit elements such as discrete passive components.

### SUMMARY

In accordance with a number of implementations, the present disclosure relates to an assembly for fabricating a packaged module. The assembly includes a packaging substrate having a surface, and an array of conductive pads implemented on the surface. The assembly further includes a conductive post formed over each conductive pad, with the conductive post including a first portion having a lateral dimension formed over the conductive pad and a second portion having a lateral dimension formed over the first portion. The lateral dimension of the first portion is less than the lateral dimension of the second portion. In some embodiments, the assembly can further include a dielectric layer implemented over the surface to cover the conductive pads and surround the first portion of each conductive post.

In some embodiments, the array of conductive pads can be arranged so that the corresponding conductive posts allow mounting of a packaged module having the assembly on a circuit board. The array of conductive pads can be arranged to provide an inner region configured allow mounting of a component on the surface.

In some embodiments, each conductive post can have a height dimension selected to provide a volume about the inner region, with the volume having a height sufficiently large to accommodate the component when the package module with the assembly is mounted on the circuit board.

In some embodiments, a lateral dimension of each of at least some of the conductive pads can be less than the lateral dimension of second portion of the respective conductive post. The lateral dimension of the respective conductive pad being less than the lateral dimension of the second portion of the respective conductive post can result in a post pitch between neighboring conductive posts not being limited by a minimum lateral separation distance between the respective conductive pads. The neighboring conductive posts having a post pitch similar to a comparable pair of conductive posts formed over respective conductive pads each having a lateral dimension larger than a lateral dimension of each comparable conductive post can result in an increased lateral region between the neighboring conductive pads. The increased lateral region between the neighboring conductive pads can be sufficiently large to allow routing of a conductive trace therethrough.

In some embodiments, at least two of the conductive posts can be electrically connected through their respective conductive pads. The at least two electrically-connected conductive posts can include a pair of neighboring conductive posts, such that an extended conductive pad form an electrically-connected pair of conductive pads for the pair of neighboring conductive posts. The at least two electrically-connected conductive posts can be electrically connected to or connectable to a ground node.

In some embodiments, the array of conductive pads can include the conductive pads being arranged to form a perimeter around the inner region. The array of conductive pads can further include additional conductive pads arranged in a section adjacent to a respective section of the perimeter.

In some embodiments, the dielectric layer can be dimensioned to surround substantially all of the first portion of each conductive post. The dielectric layer can include a surface that is substantially coplanar with a plane where the first portion transitions to the second portion of the conductive post. The dielectric layer can include a solder resist material or a prepreg material.

In some embodiments, each conductive pad can be formed from copper. In some embodiments, each conductive post can be formed from copper.

In some embodiments, the assembly can further include a seed layer implemented between the surface and each conductive pad.

In some embodiments, the assembly can further include a protective layer implemented to cover exposed portions of each conductive post. The protective layer can include an organic solderability preservative coating or a nickel/gold coating.

In some embodiments, the assembly can further include one or more conductive traces formed on the surface, with at least one conductive trace being routed through a region between a pair of neighboring conductive pads.

In some embodiments, the packaging substrate can further include another surface opposite from the surface. The other surface can be configured to allow mounting of one or more components thereon, such that a packaged module having the assembly is a dual-sided module. In some embodiments, the packaging substrate can be implemented as a laminate substrate having a plurality of layers, and the surface can be on an underside of the laminate substrate when the dual-sided module having the assembly is mounted on a circuit board.

In some implementations, the present disclosure relates to a packaged module that includes a packaging substrate having a first side and a second side, and an array of conductive assemblies implemented on the second side of the packaging substrate. Tach conductive assembly includes a conductive pad, a conductive post including a first portion having a lateral dimension formed over the conductive pad and a second portion having a lateral dimension formed over the first portion, with the lateral dimension of the first portion being less than the lateral dimension of the second portion. The packaged module can further include a dielectric layer implemented on the second side of the packaging substrate to cover the conductive pads and surround the first portion of each conductive post. The packaged module can further include a component mounted over the second side of the packaging substrate and within an inner region defined by the array of conductive assemblies, such that the packaged module is capable of being mounted on a circuit board with the conductive posts.

In some embodiments, the packaged module can further include one or more components mounted over the first side of the packaging substrate. In some embodiments, the packaged module can further include an overmold formed over the first side of the packaging substrate to encapsulate the one or more components.

In some embodiments, the packaged module can further include an overmold formed over the second side of the packaging substrate to encapsulate the component mounted thereto and to surround some or all of a side wall of each conductive post.

In some implementations, the present disclosure relates to a wireless device that includes an antenna and a radio-frequency circuit configured to operate with the antenna. At least some of the radio-frequency circuit is implemented in a packaged module including a packaging substrate having a first side and a second side, and an array of conductive assemblies implemented on the second side of the packaging substrate. Each conductive assembly includes a conductive pad, a conductive post including a first portion having a lateral dimension formed over the conductive pad and a second portion having a lateral dimension formed over the first portion. The lateral dimension of the first portion is less than the lateral dimension of the second portion. The packaged module can further include a dielectric layer implemented on the second side of the packaging substrate to cover the conductive pads and surround the first portion of each conductive post. The packaged module can further include a component mounted over the second side of the packaging substrate and within an inner region defined by the array of conductive assemblies, such that the packaged module is capable of being mounted on a circuit board with the conductive posts.

According to some implementations, the present disclosure relates to a method for fabricating an assembly for a packaged module. The method includes forming or providing a packaging substrate having a surface, and implementing an array of conductive pads over the surface. The method can include forming a dielectric layer over the array of conductive pads, and forming an opening having a lateral dimension through the dielectric layer over each of the conductive pads. The method further includes forming a conductive post over each conductive pad, such that the conductive post includes a first portion that substantially fills the respective opening. The conductive post further includes a second portion having a lateral dimension formed over the first position, with the lateral dimension of the opening being less than the lateral dimension of the second portion.

In some embodiments, the forming of the array of conductive pads can include forming a conductive seed layer on the surface, patterning the conductive pads on the conductive seed layer, and removing portions of the conductive seed layer not covered by the conductive pads. The conductive seed layer can include a copper seed layer, and each conductive pad can include copper.

In some embodiments, the patterning of the conductive pads can include a modified semi-additive process (mSAP), and the removing of the portions of the conductive seed layer can include an etching process.

In some embodiments, the forming of the conductive posts can include forming a conductive seed layer to cover the dielectric layer, the openings, and a surface of each conductive pad exposed by the respective opening. The forming of the conductive seed layer can include forming a copper seed layer with an electroless copper (E'less Cu) plating process.

In some embodiments, the forming of the conductive posts can include forming a dry fill layer over the dielectric layer and the openings of the dielectric layer, forming an opening through the dry fill layer over each conductive pad, forming the conductive post to fill some or all of the respective opening of dry fill layer, and removing the dry fill layer after the formation of the conductive posts. The forming of each conductive post can include a copper plating process, and the removing of the dry fill layer can include an etching process.

In some embodiments, the method can further include forming a protective coating to cover exposed surfaces of the conductive posts. The protective coating can include a solderability preservative coating. The solderability preservative coating can include an organic solderability preservative (OSP) coating or a nickel/gold (Ni/Au) coating.

According to some implementations, the present disclosure relates to a method for fabricating a packaged module. The method includes forming or providing an assembly that includes a packaging substrate having a first side and a second side, an array of conductive pads implemented on the second side, a conductive post formed over each conductive pad such that the conductive post includes a first portion having a lateral dimension formed over the conductive pad and a second portion having a lateral dimension formed over the first portion, and such that the lateral dimension of the first portion is less than the lateral dimension of the second portion, and a dielectric layer implemented over the second side to cover the conductive pads and surround the first portion of each conductive post. The method further includes mounting a component over the second side of the packaging substrate and within an inner region defined by the array of conductive pads, such that the packaged module is capable of being mounted on a circuit board with the conductive posts.

In some embodiments, the method can further include mounting one or more components over the first side of the packaging substrate. In some embodiments, the method can further include forming an overmold over the first side of the packaging substrate to encapsulate the one or more components.

In some embodiments, the method can further include forming an overmold over the second side of the packaging substrate to encapsulate the component mounted thereto and to surround some or all of a side wall of each conductive post.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a side view of two conventional conductive posts that can be implemented on a surface of a packaging substrate.

FIG. 2 shows a side view of two conductive posts having one or more features as described herein.

FIG. 3 demonstrates how more assemblies of posts and pads of FIG. 2 can be implemented in a given space when compared to assemblies of posts and pads of FIG. 1.

FIG. 4A shows an example of an assembly of conductive pad and post.

FIG. 4B shows another example of an assembly of conductive pad and post.

FIG. 4C shows yet another example of an assembly of conductive pad and post.

FIG. 5 shows a side view of an assembly of conductive pad and post similar to those in the examples of FIGS. 2 and 3.

FIGS. 6A to 6D show non-limiting examples of plan-view sectional shapes that can be implemented for conductive pads and first portions of conductive posts.

FIG. 7A shows a plan view of a mounting side of a unit having an array of conventional assemblies of conductive pads and conductive posts implemented on a packaging substrate, with each assembly being similar to the example of FIG. 1.

FIG. 7B shows a side sectional view of the unit of FIG. 7A.

FIG. 8A shows a plan view of a mounting side of a unit having an array of assemblies of conductive pads and conductive posts implemented on a packaging substrate, with each assembly being similar to the example of FIGS. 2 and 3.

FIG. 8B shows a side sectional view of the unit of FIG. 8A.

FIGS. 9A to 91 show various stages of a process that can be implemented to fabricate a packaging unit similar to the unit of FIGS. 7A and 7B.

FIGS. 10A to 10J show various stages of a process that can be implemented to fabricate a packaging unit similar to the unit of FIGS. 8A and 8B.

FIG. 11 shows that in some embodiments, a conductive post having one or more features as described herein can be electrically connected to one or more other conductive post(s).

FIG. 12 shows that in some embodiments, an assembly similar to the assembly of FIGS. 8A, 8B and/or 10J can be utilized to fabricate a packaged module.

FIG. 13A shows an example where an assembly for fabricating a packaged module can be implemented while multiple assembly units are in an array format.

FIG. 13B shows another example where an assembly for fabricating a packaged module can be implemented while multiple assembly units are in an array format.

FIG. 14 depicts an example wireless device that includes a packaged module having one or more advantageous features described herein.

### DETAILED DESCRIPTION OF SOME EMBODIMENTS

The headings provided herein, if any, are for convenience only and do not necessarily affect the scope or meaning of the claimed invention.

In many electronics applications including radio-frequency (RF) applications, integrated circuits and/or circuit elements are implemented as parts of packaged modules. A packaged module typically includes a packaging substrate configured to receive and support a plurality of components such as semiconductor die and/or circuit elements such as discrete passive components. Some or all of such components can be mounted on the upper side of the packaging substrate, and an upper overmold can be provided to encapsulate such components.

In some embodiments, the lower side of the packaging substrate can be configured to allow mounting of the packaged module onto a circuit board. For example, an array of conductive posts such as copper (Cu) posts can be provided on the lower side of the packaging substrate to allow the package module to be secured to the circuit board and to provide electrical connections for the packaged module.

In some embodiments, one or more lower side components such as one or more die can be mounted on the lower side of the packaging substrate. To accommodate such lower side component(s), the foregoing array of conductive posts can be arranged to provide an appropriate amount of space for the lower side component(s).

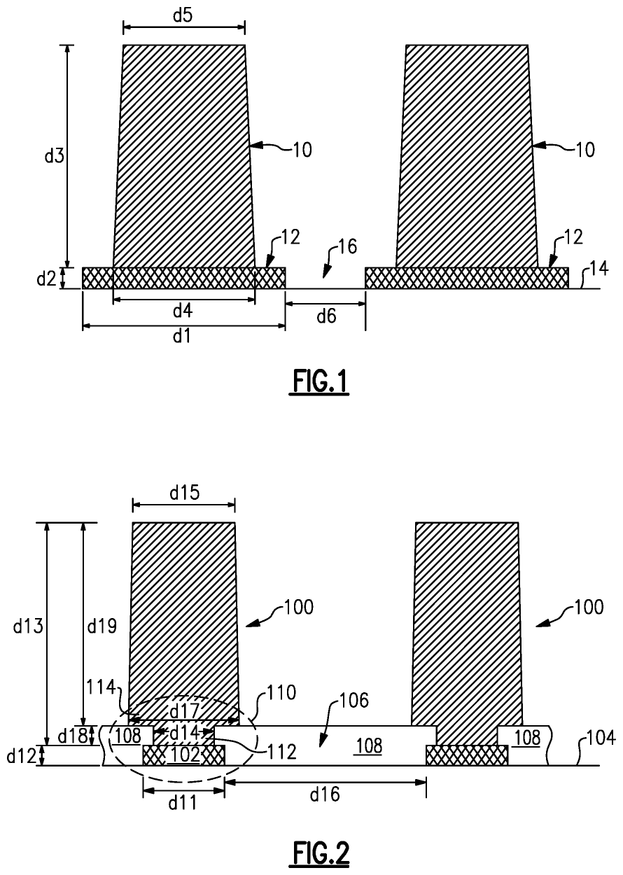

FIG. 1 shows a side view of two conventional conductive posts 10 that can be implemented on a surface 14 of a packaging substrate. Such a surface can be a lower side of the packaging substrate when a packaged module based on the packaging substrate is mounted on a circuit board.

In the example of FIG. 1, each conductive post 10 is shown to be formed over a respective conductive pad 12. The conductive pad 12 is shown to be formed on the surface 14, and has a lateral dimension d1 and a thickness d2. The conductive post 10 is shown to have a height dimension d3, a base dimension d4, and an end lateral dimension d5. It will be understood that the lateral dimensions d4 and d5 associated with the post 10 may or may not be the same. For example, if d4 ≈d5, the side sectional shape of the post 10 is approximately a rectangular shape. In another example if d4 >d5, the side sectional shape of the post is approximately an isosceles trapezoid shape.

In the example of FIG. 1, the lateral dimension d1 of the conductive pad 12 is greater than the base dimension d4 of the conductive post 10. Thus, the closest separation distance between the two neighboring conductive assemblies of pad and post is indicated as d6 which is a lateral separation distance between the two neighboring pads. Accordingly, a lateral distance between a location (e.g., center) of one post and the corresponding location of the neighboring post, also referred to herein as a post pitch, is limited by the lateral dimension d1 of the conductive pad 12.

It is noted that in the example of FIG. 1, if one assumes that the two conductive assemblies of pad 12 and post 10 are at the closest allowed separation such that the corresponding post pitch is the minimum allowed, introduction of a conductive feature such as a conductive trace between the two conductive assemblies is not desirable or feasible. Accordingly, conductive assemblies of FIG. 1 are typically implemented in a single-row arrangement, since electrical connections by conductive traces on the surface through the row of relatively large pads are not possible or practical.

It is also noted that in the example of FIG. 1, a process for fabricating the conductive assemblies of pad 12 and post 10 can result in a loss of conductive trace thickness for a conductive trace in a keep-out zone relative to the conductive assemblies. An example of such a process is described herein in greater detail

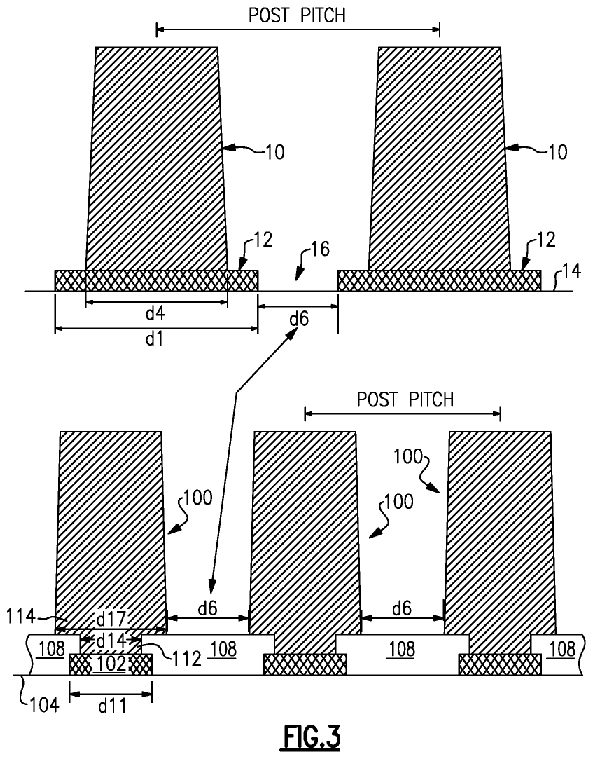

FIG. 2 shows a side view of two conductive posts 100 having one or more features as described herein. Such example conductive posts are shown to be implemented on a surface 104 of a packaging substrate. Similar to the example of FIG. 1, such a surface can be a lower side of the packaging substrate when a packaged module based on the packaging substrate is mounted on a circuit board.

In the example of FIG. 2, each conductive post 100 is shown to be formed over a respective conductive pad 102. The conductive pad 102 is shown to be formed on the surface 104, and has a lateral dimension d11 and a thickness d12.

The conductive post 100 is shown to include a first portion 112 in electrical contact with the conductive pad 102 and having a thickness d18 and a lateral dimension d14. The conductive post 100 is shown to further include a second portion 114 that extends away from the contact pad 102 by a height dimension d19 relative to the first portion 112. Thus, the conductive post 100 is shown to have an overall height dimension d13 relative to the conductive pad 102.

The conductive post 100 is shown to have a dimension d17 at the base of the second portion 114, and an end lateral dimension d15. It will be understood that the lateral dimensions d17 and d15 associated with the post 100 may or may not be the same. For example, if d17≈d15, the side sectional shape of the post 100 is approximately a rectangular shape. In another example if d17 >d15, the side sectional shape of the post is approximately an isosceles trapezoid shape.

In some embodiments, the first and second portions 112, 114 of the conductive post 100 can be formed from same conductive material. Although various examples are described herein in such a context, it will be understood that the first and second portions 112, 114 of the conductive post can also be implemented with different materials.

In the example of FIG. 2, the first portion 112 of the conductive post 100 is in electrical contact with the conductive pad 102. In some embodiments, the first portion 112 can be in direct engagement with the conductive pad 102. In some embodiments, one or more conductive layers can be provided between the first portion 112 and the conductive pad 102.

In the example of FIG. 2, a dielectric layer 108 is shown to be provided over the surface 104 of the packaging substrate. Such a dielectric layer can include an opening formed over the conductive pad 102, and the opening can substantially determine the shape of the first portion 112 of the conductive post 100. In some embodiments, the dielectric layer 108 can be formed from, for example, solder resist material or prepreg material. Examples related to formation of such a dielectric layer are described herein in greater detail.

In the example of FIG. 2, the lateral dimension d11 of the conductive pad 102 is less than the largest lateral dimension (e.g., d17 at the base of the second portion 114) of the conductive post 100. Thus, the closest separation distance between the two neighboring conductive assemblies of pad and post is not the separation distance d16 between the two neighboring pads, but between the bases of the second portions of the two neighboring posts. Accordingly, a post pitch is not limited by the lateral dimension d11 of the conductive pad 102.

In the example of FIG. 2, dimensions of the conductive post 100 can be selected to provide desirable electrical and mechanical properties. For example, the lateral dimension (e.g., d17) of the conductive post 100 can be selected to provide sufficient but not excessive shear force resistance to prevent mechanical failure of the conductive post 100 or its attachment to the conductive pad 102. Such a lateral dimension (d17) can be significantly smaller than the base dimension d4, and even smaller than the lateral dimension d1 of the conductive pad 12, of the conventional configuration of FIG. 1. Thus, the conductive posts 100 of FIG. 2 can be arranged with a significantly lower post pitch when compared to the example of FIG. 1.

It is noted that in the example of FIG. 2, if one assumes that the post pitch between the two conductive posts 100 is similar to the post pitch in the example of FIG. 1, one can see that the space between the two conductive pads 102 of FIG. 2 is significantly larger than the space between the two conductive pads 12 of FIG. 1. Accordingly, such an increased space can allow implementation of a conductive trace between the conductive pads 102 without significant electrical performance degradation.

In some embodiments, conductive posts and pads as described herein can be configured to provide the foregoing reduced post pitch, as well as allow the foregoing implementation of a conductive trace between conductive pads.

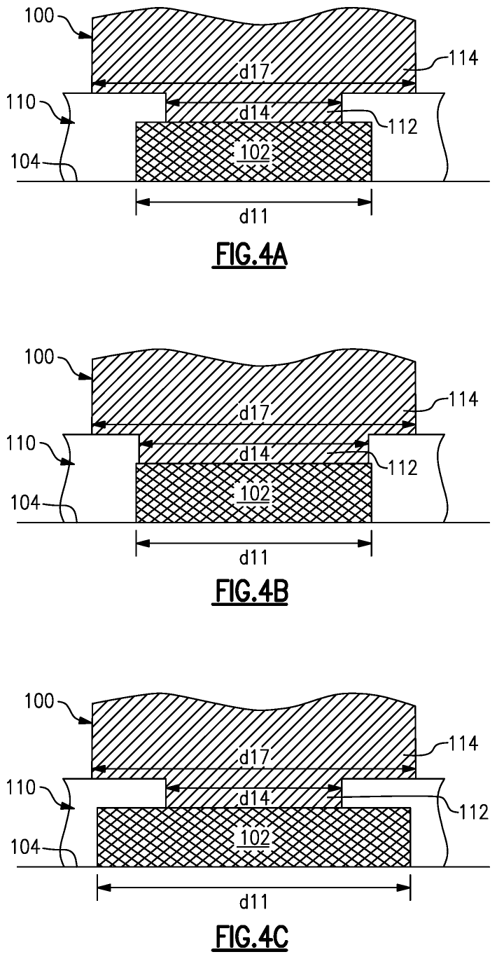

Referring to the examples of FIGS. 1 and 2, suppose that the dimension d6 (in FIG. 1) is the minimum allowed lateral dimension between two assemblies of posts and pads, and that the reduced lateral dimension of each post 100 in FIG. 2 is selected to provide desired electrical and mechanical properties as described herein. With such assumptions, FIG. 3 demonstrates how more assemblies of posts and pads of FIG. 2 can be implemented in a given space when compared to assemblies of posts and pads of FIG. 1.

In FIG. 3, the upper pair of assemblies of posts and pad is similar to the example of FIG. 1, with the assumption that the dimension d6 is the minimum allowed lateral dimension between the assemblies. The lower group of assemblies of posts and pads includes the assemblies of FIG. 2 arranged so that the closest distance between two neighboring assemblies is also approximately d6. Arranged in the foregoing manner, one can see that within a given space, more assemblies of posts and pads of FIG. 2 can be implemented than those of FIG. 1.

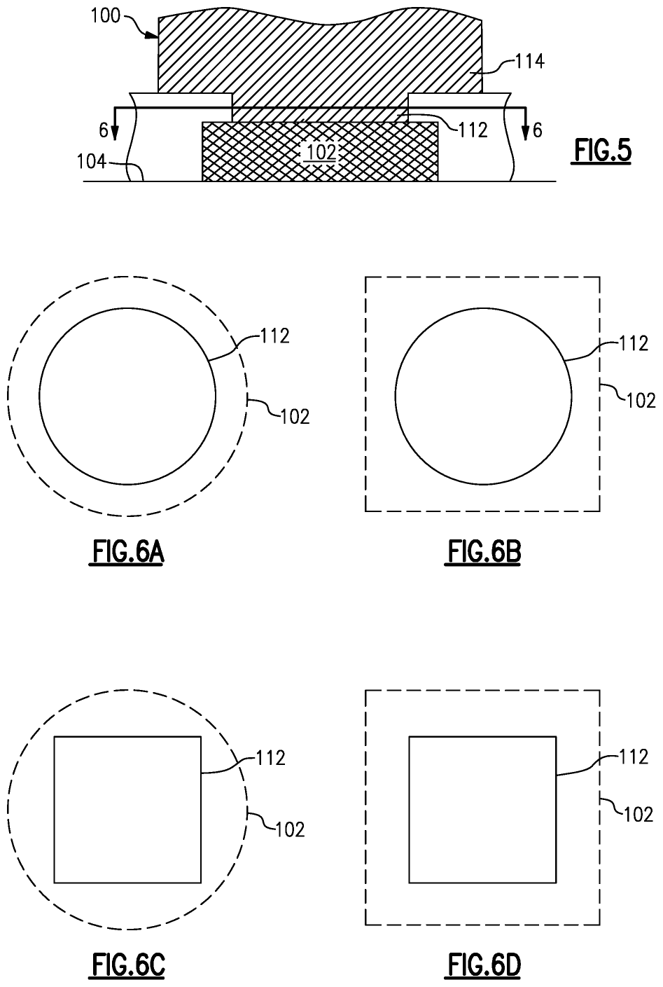

FIG. 4A shows an enlarged view of an assembly of conductive pad 102 and post 100 similar to those in the examples of FIGS. 2 and 3. Such an assembly of conductive pad and post is shown to be dimensioned so that d14<d11<d17.

FIG. 4B shows that in some embodiments, an assembly of conductive pad 102 and post 100 as described herein can be dimensioned so that d14<d17 and d14 ≈d11. For the latter, lateral dimensions of d14 and d11 can be within 0%, 1%, 2%, 3%, 4% or 5% of each other.

FIG. 4C shows that in some embodiments, an assembly of conductive pad 102 and post 100 as described herein can be dimensioned so that d14<d17 and d17≈d11. For the latter, lateral dimensions of d17 and d11 can be within 0%, 1%, 2%, 3%, 4% or 5% of each other.

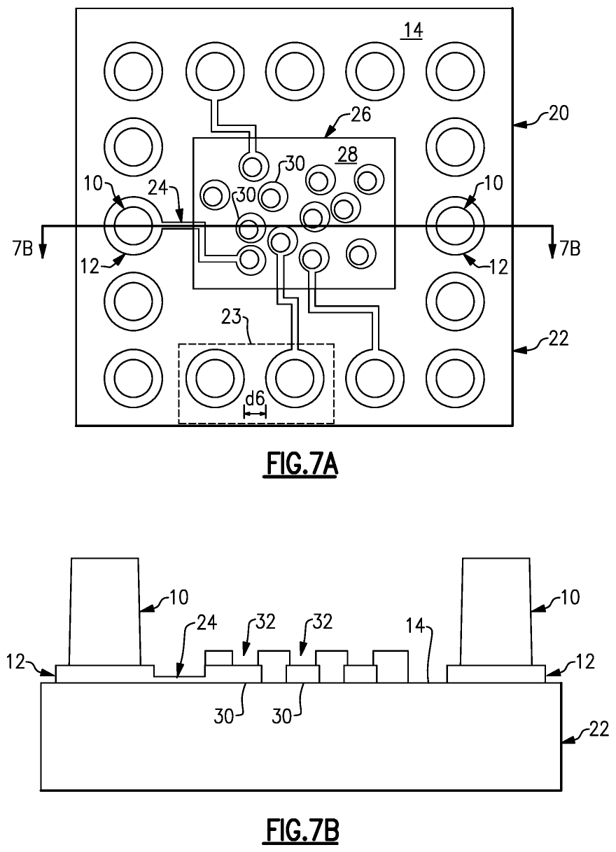

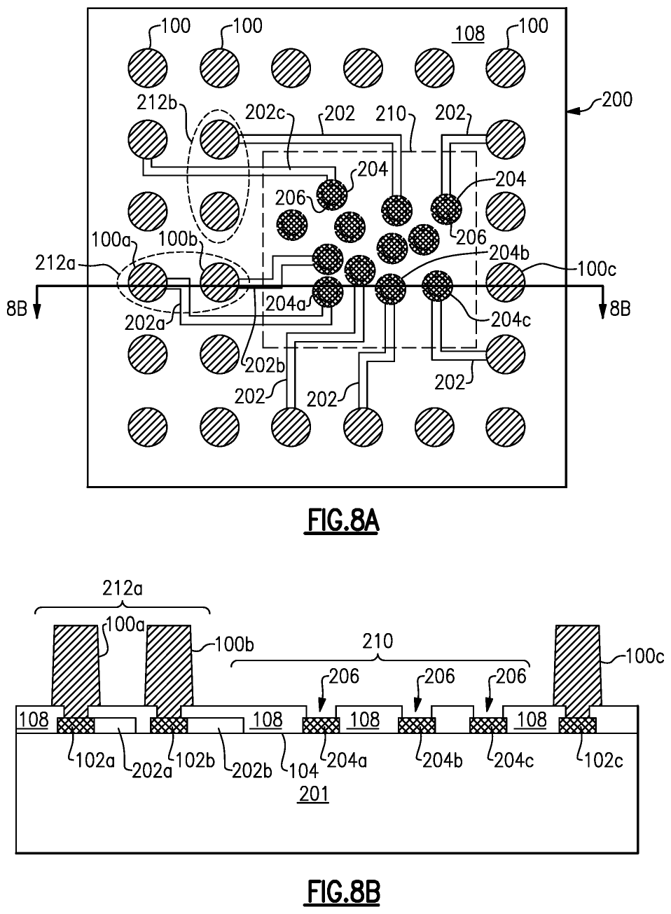

FIGS. 5 and 6 show that an assembly of conductive pad 102 and post 100 as described herein can have different plan-view sectional shapes. More particularly, FIG. 5 shows a side view of an assembly of conductive pad 102 and post 100 similar to those in the examples of FIGS. 2 and 3. FIGS. 6A to 6D show non-limiting examples of plan-view sectional shapes that can be implemented for conductive pads 102 and first portions 112 of conductive posts 100.

For example, FIG. 6A shows that in some embodiments, a conductive pad 102 can have a circular plan-view sectional shape, and a first portion 112 of a conductive post (100 in FIG. 5) can also have a circular plan-view sectional shape.

In another example, FIG. 6B shows that in some embodiments, a conductive pad 102 can have a rectangular (e.g., square) plan-view sectional shape, and a first portion 112 of a conductive post (100 in FIG. 5) can have a circular plan-view sectional shape.

In yet another example, FIG. 6C shows that in some embodiments, a conductive pad 102 can have a circular plan-view sectional shape, and a first portion 112 of a conductive post (100 in FIG. 5) can have a rectangular (e.g., square) plan-view sectional shape.

In yet another example, FIG. 6D shows that in some embodiments, a conductive pad 102 can have a rectangular (e.g., square) plan-view sectional shape, and a first portion 112 of a conductive post (100 in FIG. 5) can also have a rectangular (e.g., square) plan-view sectional shape.

Although not shown, it will be understood that second portions 114 of conductive posts 100 can also have different plan-view sectional shapes relative to respective first portions 112 and/or respective conductive pads 102.

Although not shown, it will be understood that other plan-view sectional shapes can also be utilized for some or all of first and second portions 112, 114 of conductive posts 100 and conductive pads 102 having one or more features as described herein. Such other shapes can include, for example, curved shapes such as elliptical shapes, non-rectangular polygon shapes, or some combination thereof.

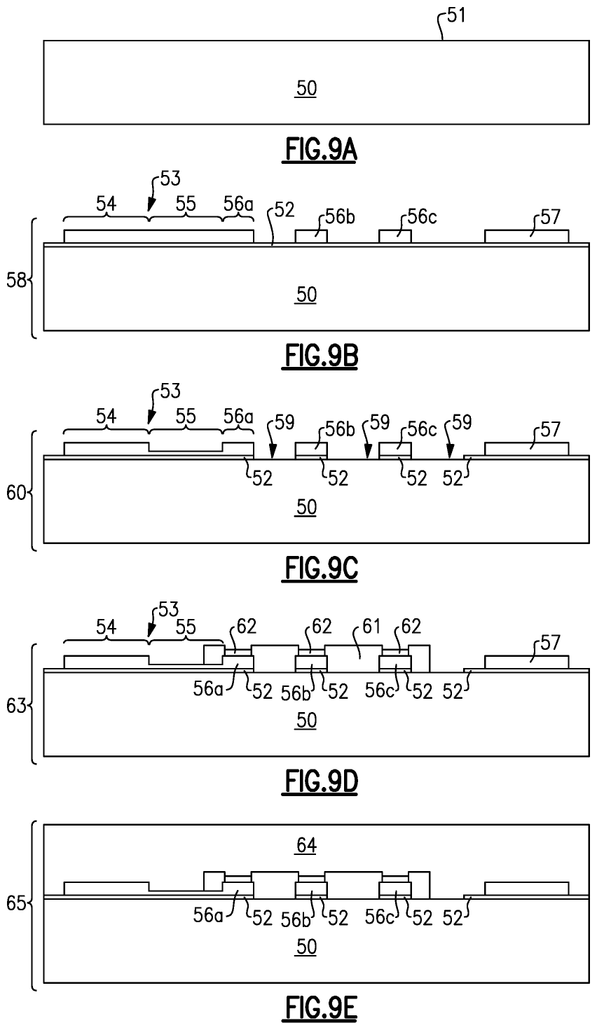

FIG. 7A shows a plan view of a mounting side of a unit 20 having an array of conventional assemblies of conductive pads 12 and conductive posts 10 implemented on a packaging substrate 22, with each assembly being similar to the example of FIG. 1. FIG. 7B shows a side sectional view of the unit 20 of FIG. 7A. It will be understood that the unit 20 as shown in FIGS. 7A and 7B can be utilized to mount various components thereto (e.g., on both sides of the substrate 22) to fabricate a packaged module.

In the example of FIGS. 7A and 7B, a plurality of assemblies of conductive pads 12 and conductive posts 10 are shown to be arranged to form a perimeter on a surface 14 of the packaging substrate 22. It is noted that such assemblies are arranged to be in a single line on or along any section of the perimeter. Such a configuration is required when the assemblies are arranged to provide minimum or reduced post pitch (e.g., a pair of assemblies indicated as 23 separated by a minimum dimension d6), such that routing of a conductive trace is not allowed in design. For example, if a second row of assemblies was implemented inward from the row of assemblies including the pair 23, routing of conductive traces on the surface 14 from the outer row of assemblies through the inner row of assemblies would not be allowed.

In the example of FIGS. 7A and 7B, an inner region 26 is shown to be provided and configured to allow mounting of a component (e.g., a die) thereon. Such an inner region is shown to include a plurality of conductive pads 30, with a portion of each pad 30 being exposed through a respective opening 32 through a dielectric layer 28. Such openings can be utilized to allow mounting of the component by, for example, solder connections.

In the example of FIGS. 7A and 7B, a region between the inner region 26 and the inner boundary of the perimeter of assemblies (of conductive pads 12 and conductive posts 10) is typically a keep-out region. One or more conductive traces may be formed through such a keep-out region to provide connectivity between some of the perimeter of assemblies and the respective conductive pads 30 of the inner region. However, each of such conductive trace(s) is electrically connected to a respective conductive pad but sufficiently distanced from other conductive pad(s).

Referring to FIGS. 7A and 7B, it is noted that conductive trace 24 is an example of such traces present in the keep-out region. As shown in FIG. 7B, such a conductive trace can suffer from being thinned during a fabrication process to produce the unit 20. Examples related to such a fabrication process is described herein in greater detail.

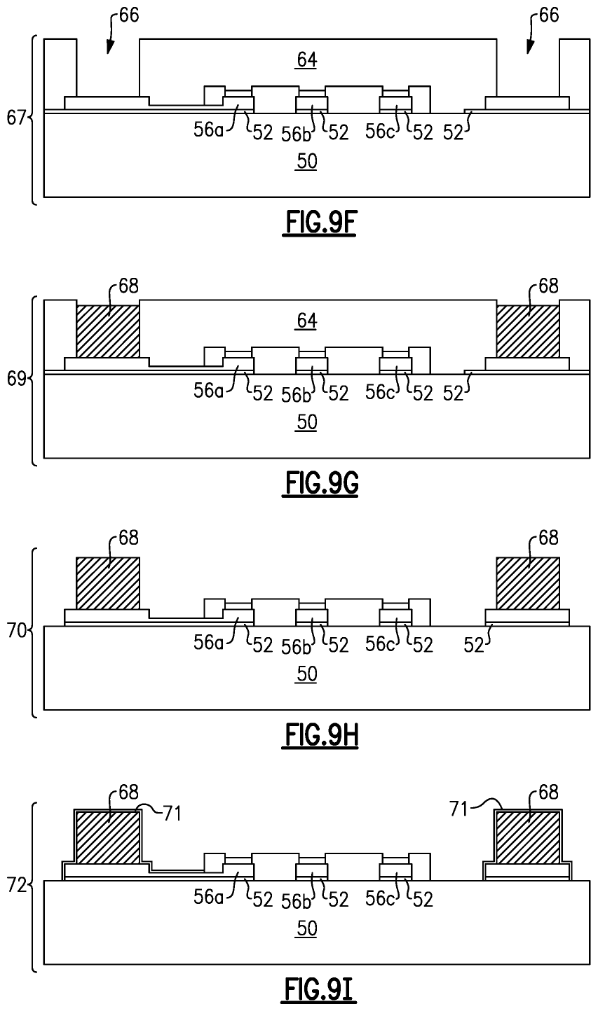

FIG. 8A shows a plan view of a mounting side of a unit 200 having an array of assemblies of conductive pads 102 and conductive posts 100 implemented on a packaging substrate 201, with each assembly being similar to the example of FIGS. 2 and 3. FIG. 8B shows a side sectional view of the unit 200 of FIG. 8A. It will be understood that the unit 200 as shown in FIGS. 8A and 8B can be utilized to mount various components thereto (e.g., on both sides of the substrate 201) to fabricate a packaged module.

In the example of FIGS. 8A and 8B, a plurality of assemblies of conductive pads 102 and conductive posts 100 are shown to be arranged to form a perimeter on a surface 104 of the packaging substrate 201. Additionally, a line of assemblies of conductive pads 102 and conductive posts 100, including a pair indicated as 212b, is shown to be implemented inward of the left portion of the perimeter.

It is noted that the foregoing assemblies shown in FIGS. 8A and 8B can be arranged to be in more than one line due to some or all of the properties of each assembly of conductive pad 102 and conductive post 100 as described herein in reference to FIGS. 2 and 3. Such properties allow the assemblies to be arranged to provide a post pitch where routing of a conductive trace is allowed in design.

For example, a conductive trace 202a is shown to be routed through a region between a pair of assemblies 212a having conductive pads and conductive posts 100a, 100b. In this example, the conductive trace 202a is electrically connected to one of the pair of assemblies, and could cause electrical interference between it (202a) and the other assembly, if not for the properties of the assemblies as described herein.

In another example, a conductive trace 202c is shown to be routed through a region between a pair of assemblies 212b. In this example, the conductive trace 202c is electrically connected to a third assembly, and could cause electrical interference between it (202c) and either or both of the assemblies of the pair 212b, if not for the properties of the assemblies as described herein.

In the example of FIGS. 8A and 8B, an inner region generally indicated as 210 is shown to be provided and configured to allow mounting of a component (e.g., a die) thereon. Such an inner region is shown to include a plurality of conductive pads 204, with a portion of each pad 204 being exposed through a respective opening 206 through a dielectric layer 108. Such openings can be utilized to allow mounting of the component by, for example, solder connections.

In the example of FIGS. 8A and 8B, a region between the inner region 210 and the inner boundary of the inner-most perimeter of assemblies (of conductive pads 102 and conductive posts 100) can be a keep-out region. One or more conductive traces may be formed through such a keep-out region to provide connectivity between some of the assemblies and the respective conductive pads 204 of the inner region 210. Conductive traces 202, including traces indicated as 202a, 202b, 202c are examples of such traces. As described herein, a fabrication process as described herein can be implemented such that conductive traces are not thinned in the keep-out region. Examples related to such a fabrication process is described herein in greater detail.

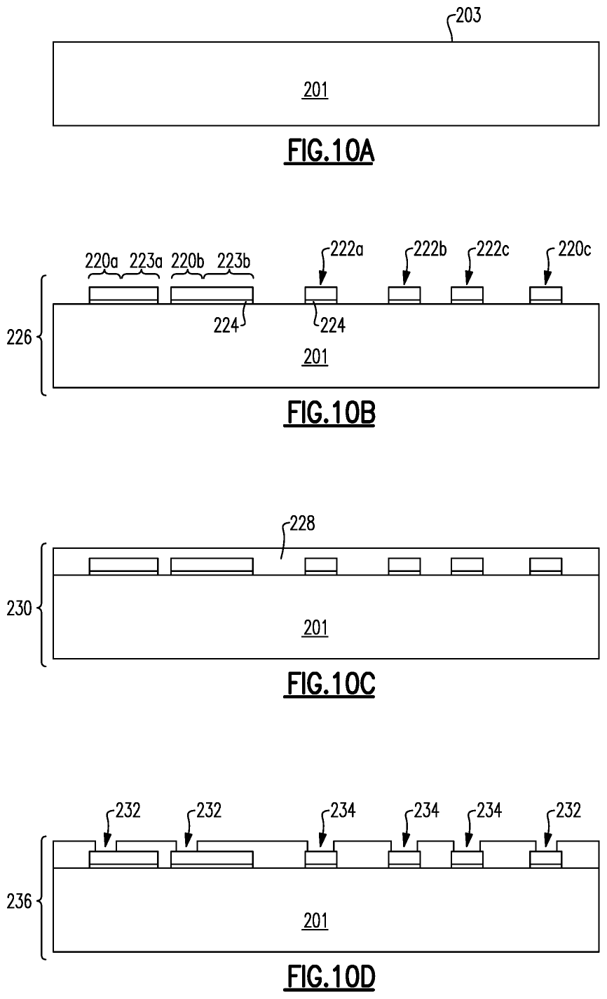

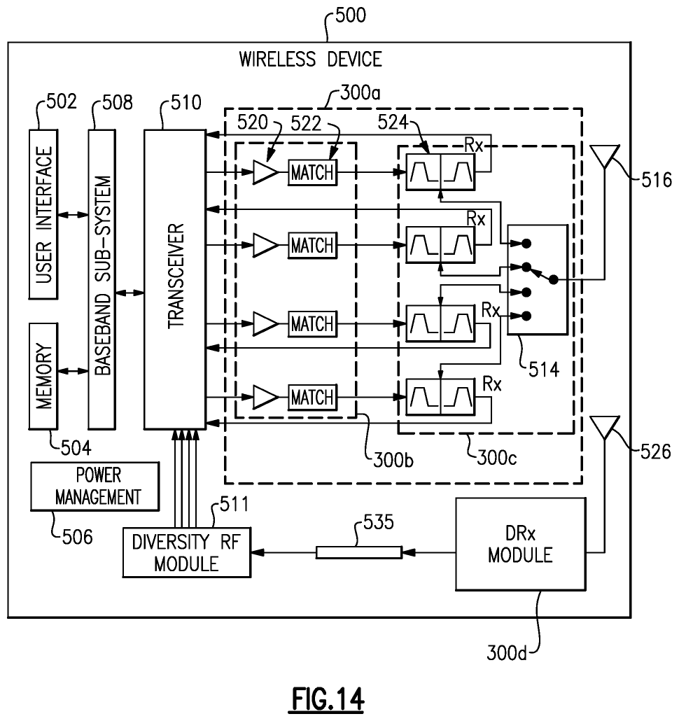

FIGS. 9A to 91 show various stages of a process that can be implemented to fabricate a packaging unit similar to the unit 20 of FIGS. 7A and 7B.

Referring to FIG. 9A, a packaging substrate 50 having a surface 51 can be provided or formed. Such a packaging substrate can include, for example, a plurality of laminate layers, and various electrical connection features can be implemented on and/or through some or all of such laminate layers. Such electrical connection features can include a ground plane.

In FIG. 9B, a conductive seed layer 52 such as a copper (Cu) seed layer can be formed on the surface (51 in FIG. 9A) of the packaging substrate 50. Then, conductive pads and conductive traces can be formed over the seed layer 52 utilizing a patterning process (e.g., modified semi-additive process (mSAP)) to provide an assembly 58. In FIG. 9B, conductive pads for conductive posts are indicated as 54 and 57, conductive pads for an inner region (26 in FIGS. 7A and 7B) are indicated as 56a, 56b, 56c, and a conductive trace is indicated as 55.

In FIG. 9C, undesired portions of the conductive seed layer 52 can be removed by, for example, an etching process to provide an assembly 60. Such an etching process is shown to provide regions 59 where the conductive seed layer 52 is removed completely. Such an etching process is also shown to remove a portion of the conductive trace 55, such that the thickness of the conductive trace 55 is reduced.

In FIG. 9D, solder resist 61 can be formed about the conductive pads (56a, 56b, 56c) of the inner region to provide an opening over each of the conductive pads. Then, a solder joint layer 62 (e.g., electroless nickel/electroless palladium/immersion gold (ENEPIG) layer) can be formed within each of such openings over the conductive pads, to provide an assembly 63.

In FIG. 9E, a dry fill material 64 can be formed over the surface (51) to encapsulate substantially all of the features formed thereon to provide an assembly 65.

In FIG. 9F, plating openings 66 can be formed over the respective conductive pads (54, 57 in FIG. 9D) to provide an assembly 67.

In FIG. 9G, conductive posts 68 can be formed within the respective openings 66 to provide an assembly 69. In some embodiments, such conductive posts can be implemented as copper (Cu) posts formed by a plating process.

In FIG. 9H, the dry fill material (64 in FIG. 9G) can be removed, and a second seed layer removal process can be implemented to provide an assembly 70. Such a second seed layer removal process can be achieved by, for example, an etching process. In FIG. 9H, such a second etching process is shown to better define the seed layer 52 with respect to the conductive pads associated with the conductive posts 68.

In FIG. 9I, a protective coating 71 can be applied to cover exposed surfaces of conductive features including the exposed conductive posts 68 and exposed portions of the corresponding conductive pads, to provide an assembly 72. Such a protective coating can be, for example, a solderability preservative coating such as an organic solderability preservative (OSP) coating. The assembly 72 can be utilized as the unit 20 of FIGS. 7A and 7B.

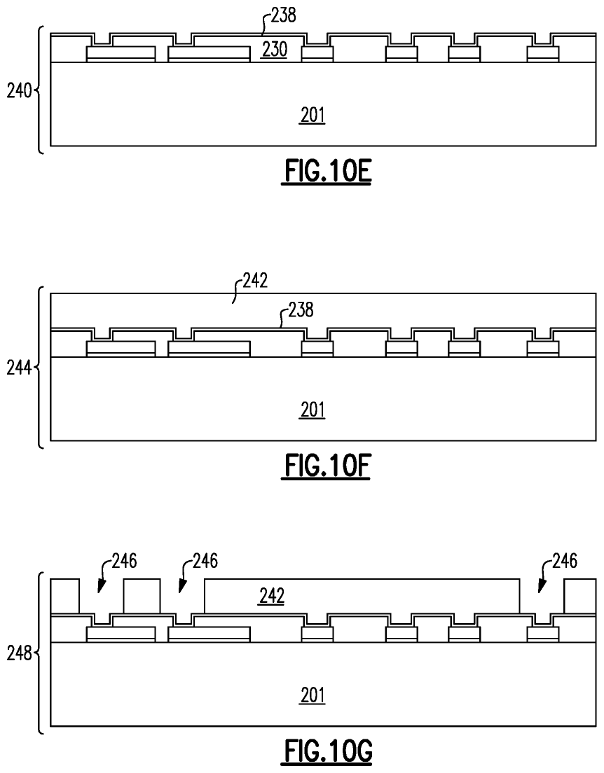

FIGS. 10A to 10J show various stages of a process that can be implemented to fabricate a packaging unit similar to the unit 200 of FIGS. 8A and 8B.

Referring to FIG. 10A, a packaging substrate 201 having a surface 203 can be provided or formed. Such a packaging substrate can include, for example, a plurality of laminate layers, and various electrical connection features can be implemented on and/or through some or all of such laminate layers. Such electrical connection features can include a ground plane. The packaging substrate 201 may or may not be the same as the packaging substrate 50 of FIG. 9A.

In FIG. 10B, a conductive seed layer 224 such as a copper (Cu) seed layer can be formed on the surface (203 in FIG. 10A) of the packaging substrate 201. Then, conductive pads and conductive traces can be formed over the seed layer 224 utilizing a patterning process (e.g., modified semi-additive process (mSAP)), and the conductive seed layer 224 can be removed (e.g., by etching) from areas not covered by the conductive pads and traces, to provide an assembly 226. In FIG. 10B, conductive pads for conductive posts are indicated as 220a, 220b, 220c, conductive pads for an inner region (210 in FIGS. 8A and 8B) are indicated as 222a, 222b, 222c, and conductive traces are indicated as 223a, 223b.

In FIG. 10C, a dielectric layer 228 can be formed over the surface (203) to substantially encapsulate the patterned contact pads and traces, to provide an assembly 230. In some embodiments, the dielectric layer 228 can be formed from solder resist material.

In FIG. 10D, an opening 232 can be formed to expose each of the conductive pads 220a, 220b, 220c, and an opening 234 can be formed to expose each of the conductive pads 222a, 222b, 222c, to provide an assembly 236. In some embodiments, the dimensions of the opening 232 can determine the dimensions of the first portion (112 in FIGS. 2 and 3) of a conductive post (100 in FIGS. 2 and 3) to be formed.

In FIG. 10E, a conductive seed layer 238 can be formed to cover substantially the entire surface having the openings 232, 234, to provide an assembly 240. In some embodiments, such a conductive seed layer can be formed utilizing an electroless copper (E'less Cu) plating process.

In FIG. 10F, a dry fill layer 242 can be formed over the conductive seed layer 238 to provide an assembly 244.

In FIG. 10G, plating openings 246 can be formed over the respective conductive pads (220a, 220b, 220c in FIG. 10B) to provide an assembly 248.

In FIG. 10H, conductive posts 250 can be formed within the respective openings 246 to provide an assembly 252. In some embodiments, such conductive posts can be implemented as copper (Cu) posts formed by a plating process.

In FIG. 10I, the dry fill layer (242 in FIG. 10H) can be removed, and portions of the conductive seed layer (238 in FIG. 10E) not covered by the conductive posts 250 can be removed, to provide an assembly 256. In some embodiments, such removal of the conductive seed layer 238 can include an etching process.

In FIG. 10J, a protective coating 260 can be applied to cover exposed surfaces of conductive features including the exposed portions of the conductive posts 250 and exposed portions of the conductive pads 204a, 204b, 204c of the inner region 258, to provide an assembly 200 that is similar to the unit 200 of FIGS. 8A and 8B. In some embodiments, such a protective coating can be, for example, a solderability preservative coating such as an organic solderability preservative (OSP) coating or a nickel/gold (Ni/Au) coating.

In the examples described herein in reference to FIGS. 3, 4A, 4B and 4C, lateral dimension d11 of each conductive pad 102 is less than or approximately equal to lateral dimension d17 of the second portion 114 of the respective conductive post 100.

It will be understood that in some embodiments, a conductive post and a respective conductive pad can be implemented in an assembly, such that lateral dimension of the conductive pad is not constrained by lateral dimension of the second portion of the conductive post. Accordingly, if d11 is lateral dimension of the conductive pad and d17 is lateral dimension of the second portion of the conductive post, d11<d17, d11≈d17, or d11>d17. In some embodiments, for the foregoing assembly, if d14 is lateral dimension of the first portion of the conductive post, d14 can be less than or approximately equal to d11.

In the side sectional view of the example of FIG. 3, each of the three conductive pads 102 is not directly connected to another conductive pad. Accordingly, in FIG. 3, each conductive post 100 is not electrically connected to another conductive post.

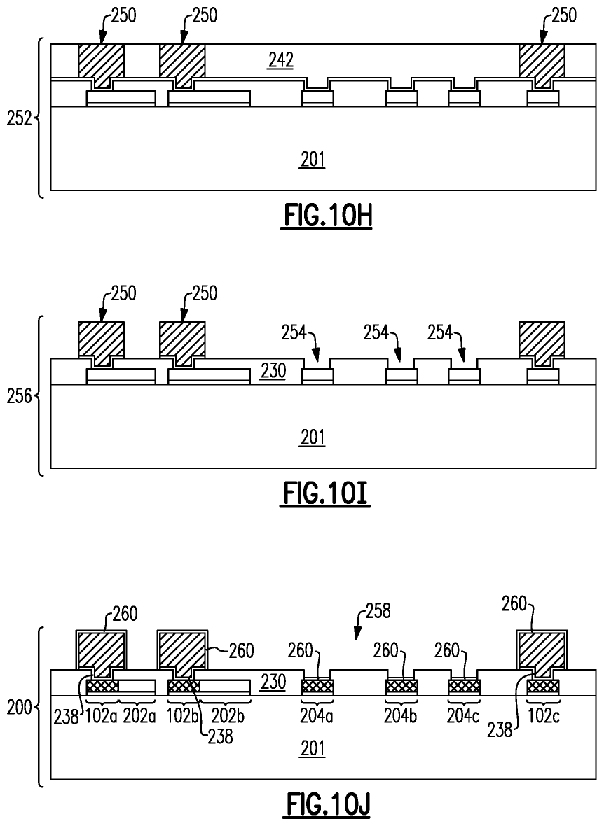

FIG. 11 shows that in some embodiments, a conductive post 100 having one or more features as described herein can be electrically connected to one or more other conductive post(s). Such an electrical connection between the plurality of conductive posts can be provided by a conductive pad 102′ that extends sufficiently to allow formation of the plurality conductive posts thereon. For example, the extended conductive pad 102′ is shown to provide an electrical connection between the middle and right conductive posts 100.

In some embodiments, the foregoing group of two or more conductive posts 100 electrically connected by the extended conductive pad 102′ can be utilized for electrical grounding purpose. Thus, the extended conductive pad 102′ can be electrically connected to a ground node located, for example, within the corresponding packaging substrate.

It will be understood that an assembly similar to the examples of FIGS. 8B and 10J can include the configuration of FIG. 11. Thus, such an assembly having the configuration of FIG. 11 can also be obtained by utilizing a fabrication process similar to the example process of FIGS. 10A to 10J.

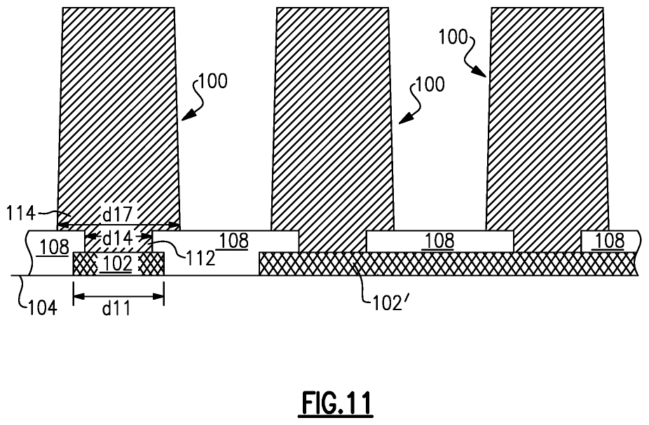

FIG. 12 shows that in some embodiments, an assembly similar to the assembly 200 of FIGS. 8A, 8B and/or 10J can be utilized to fabricate a packaged module. In some embodiments, an assembly based on the example configuration of FIG. 11 can also be utilized to fabricate such a packaged module. In FIG. 12, an example packaged module 300 is shown to include an assembly 200 similar to the assembly 200 of FIG. 10J. As described herein, such an assembly includes an inner region (258 in FIG. 10J) defined by an array of conductive posts 100 having desirable features. FIG. 12 shows that in such an inner region, an underside component 302 such as a die can be mounted with solders 304 that secure respective contact pads on the component 302 to the respective conductive pads (204 in FIG. 10J).

Referring to FIG. 12, the packaged module 300 is shown to further include an underside overmold 306 that encapsulates the underside component 302 and some or all of the sides of the conductive posts 100. In the example of FIG. 12, exposed surfaces 308 of the conductive posts 100 are shown to be approximately flush with the underside surface of the overmold 306. However, it will be understood that in some embodiments, exposed surfaces 308 of the conductive posts 100 can protrude beyond the underside surface of the overmold 306, or be recessed with respect to the underside surface of the overmold 306.

Additional examples related to underside configurations of packaged modules, as well as examples related to fabrication methods where a plurality of units can be fabricated in an array format, are described in U.S. Publication No. 2022/0319968, entitled MODULE HAVING DUAL SIDE MOLD WITH METAL POSTS, which is hereby expressly incorporated by reference herein in its entirety. In some embodiments, at least some of the examples provided in the referenced publication can utilize conductive posts 100 having one or more features as described herein.

Referring to FIG. 12, the packaged module 300 is shown to further include example components 310a, 310b mounted on the upper side of the packaging substrate 201. Such components can include, for example, die, discrete components, etc. configured and interconnected with each other and the underside component 203 to provide one or more functionalities (e.g., radio-frequency functionality) for the packaged module 300.

The packaged module 300 is shown to further include an upper-side overmold 310 that encapsulates the components 310a, 310b.

In some embodiments, the package module 300 can also include radio-frequency shielding functionality. For example, a conductive layer 314 can be formed (e.g., by conformal deposition of conductive material) to cover the upper side and at least some of the side walls of the packaged module 300, and such a conductive layer can be electrically connected to a ground plane within the packaging substrate 201.

Configured in the foregoing manner, at least the components 310a, 310b on the upper side of the packaging substrate 201 can be shielded relative to locations external to the packaged module 300. If the conductive layer 314 extends to the bottom of the side walls of the packaged module 300, as depicted in FIG. 12, shielding can also be provided for the underside component 302 relative to locations external to the packaged module 300.

In some embodiments, the array of conductive posts 100 can also provide radio-frequency shielding functionality for the underside component 302, with or without the conductive layer 314. As described herein, conductive posts 100 can be configured to allow a greater range of post pitch values. Accordingly, such post pitch flexibility can also provide greater flexibility for improved shielding performance.

In some embodiments, an assembly (e.g., 200 in FIGS. 8A and 8B, and/or 200 in FIG. 10J) for fabricating a packaged module (e.g., 300 in FIG. 12) can be implemented while multiple assembly units are in an array format.

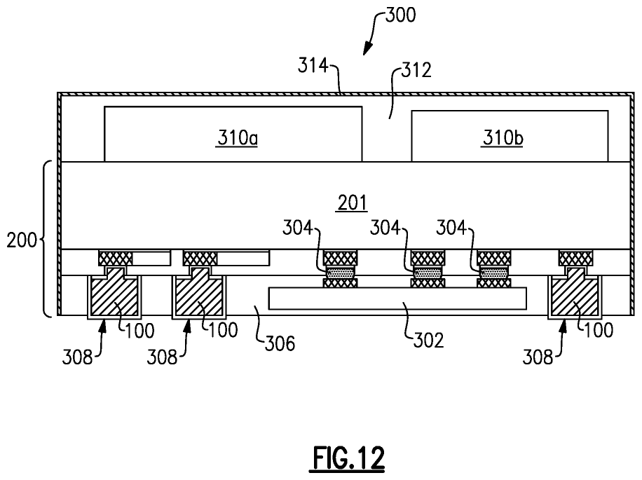

FIG. 13A shows an example of an array format 400 having an array of assemblies 200. In some embodiments, the array format 400 of FIG. 13A can have a circular shape similar to a circular shaped wafer. FIG. 13B shows another example of an array format 400 having an array of assemblies 200. In some embodiments, the array format 400 of FIG. 13B can have a rectangular panel shape. It will be understood that an array format having an array of assemblies can also be implemented in other shapes.

In some embodiments, multiple packaged modules can be fabricated utilizing an array of assemblies, such as the array format 400 of FIG. 13A or 13B. More particularly, some or all of process steps involved in fabrication of such multiple packaged modules can be achieved while in array format, and then singulated to provide multiple individual packaged modules.

For example, and in the context of the example packaged module 300 of FIG. 12, the assembly 200 can be one of multiple assemblies in an array format. Utilizing such an array of assemblies, both sides of the substrate 201 can be processed to form an array of dual sided modules, followed by a singulation process to provide multiple individual packaged modules. In the example of FIG. 12, it is noted that the shielding layer 314 can be formed on each of the singulated packaged modules.

In some implementations, a device and/or a circuit having one or more features described herein can be included in an RF electronic device such as a wireless device. In some embodiments, such a wireless device can include, for example, a cellular phone, a smart-phone, a hand-held wireless device with or without phone functionality, a wireless tablet, etc.

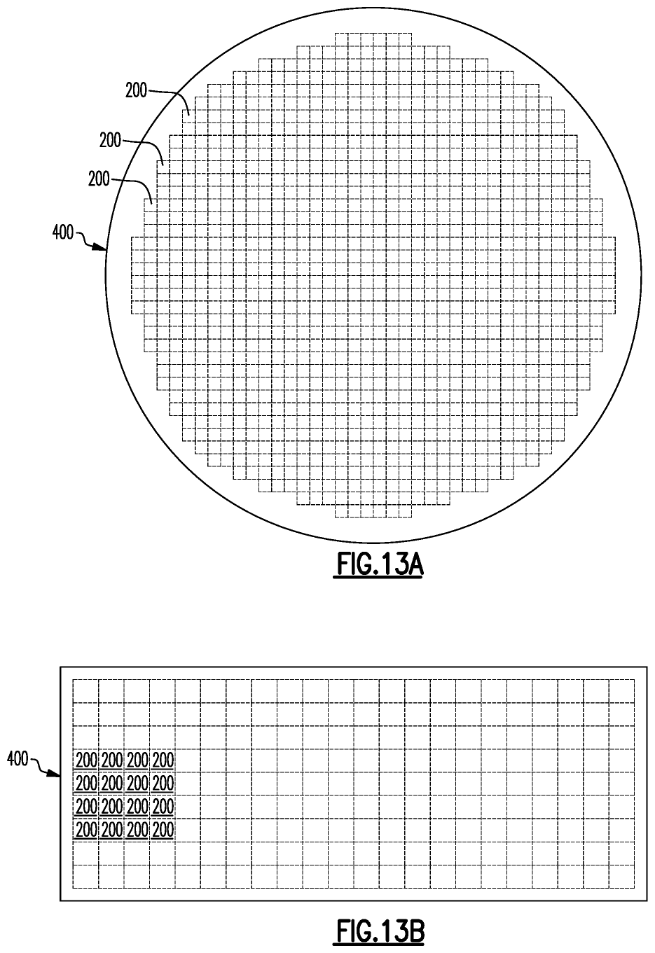

FIG. 14 depicts an example wireless device 500 having one or more advantageous features described herein. In the example of FIG. 14, an RF module having one or more features as described herein can be implemented in a number of places. For example, an RF module may be implemented as a front-end module (FEM) indicated as 300a. In another example, an RF module may be implemented as a power amplifier module (PAM) indicated as 300b. In another example, an RF module may be implemented as an antenna switch module (ASM) indicated as 300c. In another example, an RF module may be implemented as a diversity receive (DRx) module indicated as 300d. It will be understood that an RF module having one or more features as described herein can be implemented with other combinations of components.

Referring to FIG. 14, power amplifiers (PAs) 520 can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 can also be in communication with a power management component 506 that is configured to manage power for the operation of the wireless device 500.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example wireless device 500, outputs of the PAs 520 are shown to be matched (via respective match circuits 522) and routed to their respective duplexers 524. Such amplified and filtered signals can be routed to a primary antenna 516 through an antenna switch 514 for transmission. In some embodiments, the duplexers 524 can allow transmit and receive operations to be performed simultaneously using a common antenna (e.g., primary antenna 16). In FIG. 14, received signals are shown to be routed to “Rx” paths that can include, for example, a low-noise amplifier (LNA).

In the example of FIG. 14, the wireless device 500 also includes the diversity antenna 526 and the shielded DRx module 300d that receives signals from the diversity antenna 526. The shielded DRx module 300d can process the received signals and transmit the processed signals via a transmission line 535 to a diversity RF module 511 that further processes the signal before feeding the signal to the transceiver 510.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An assembly for fabricating a packaged module, the assembly comprising:
a packaging substrate having a surface;
an array of conductive pads implemented on the surface;
a conductive post formed over each conductive pad, the conductive post including a first portion having a lateral dimension formed over the conductive pad and a second portion having a lateral dimension formed over the first portion, the lateral dimension of the first portion less than the lateral dimension of the second portion; and
a dielectric layer implemented over the surface to cover the conductive pads and surround the first portion of each conductive post.

2. The assembly of claim 1 wherein the array of conductive pads is arranged so that the corresponding conductive posts allow mounting of a packaged module having the assembly on a circuit board.

3. The assembly of claim 2 wherein the array of conductive pads is arranged to provide an inner region configured allow mounting of a component on the surface.

4. The assembly of claim 3 wherein each conductive post has a height dimension selected to provide a volume about the inner region, the volume having a height sufficiently large to accommodate the component when the package module with the assembly is mounted on the circuit board.

5. The assembly of claim 3 wherein a lateral dimension of each of at least some of the conductive pads is less than the lateral dimension of second portion of the respective conductive post.

6. The assembly of claim 5 wherein the lateral dimension of the respective conductive pad being less than the lateral dimension of the second portion of the respective conductive post results in a post pitch between neighboring conductive posts not being limited by a minimum lateral separation distance between the respective conductive pads.

7. The assembly of claim 6 wherein the neighboring conductive posts having a post pitch similar to a comparable pair of conductive posts formed over respective conductive pads each having a lateral dimension larger than a lateral dimension of each comparable conductive post results in an increased lateral region between the neighboring conductive pads.

8. The assembly of claim 7 wherein the increased lateral region between the neighboring conductive pads is sufficiently large to allow routing of a conductive trace therethrough.

9. The assembly of claim 3 wherein at least two of the conductive posts are electrically connected through their respective conductive pads.

10. The assembly of claim 9 wherein the at least two electrically-connected conductive posts include a pair of neighboring conductive posts, such that an extended conductive pad form an electrically-connected pair of conductive pads for the pair of neighboring conductive posts.

11. The assembly of claim 9 wherein the at least two electrically-connected conductive posts are electrically connected to or connectable to a ground node.

12. The assembly of claim 3 wherein the array of conductive pads includes the conductive pads being arranged to form a perimeter around the inner region.

13. The assembly of claim 12 wherein the array of conductive pads further includes additional conductive pads arranged in a section adjacent to a respective section of the perimeter.

14. The assembly of claim 1 wherein the dielectric layer is dimensioned to surround substantially all of the first portion of each conductive post.

15. The assembly of claim 14 wherein the dielectric layer includes a surface that is substantially coplanar with a plane where the first portion transitions to the second portion of the conductive post.

16. The assembly of claim 14 wherein the dielectric layer includes a solder resist material or a prepreg material.

17. The assembly of claim 1 wherein each conductive pad is formed from copper.

18. The assembly of claim 1 wherein each conductive post is formed from copper.

19. The assembly of claim 1 further comprising a seed layer implemented between the surface and each conductive pad.

20. The assembly of claim 1 further comprising a protective layer implemented to cover exposed portions of each conductive post.

21. The assembly of claim 20 wherein the protective layer includes an organic solderability preservative coating or a nickel/gold coating.

22. The assembly of claim 1 further comprising one or more conductive traces formed on the surface, at least one conductive trace being routed through a region between a pair of neighboring conductive pads.

23. The assembly of claim 1 wherein the packaging substrate further includes another surface opposite from the surface, the other surface configured to allow mounting of one or more components thereon, such that a packaged module having the assembly is a dual-sided module.

24. The assembly of claim 23 wherein the packaging substrate is implemented as a laminate substrate having a plurality of layers, and the surface is on an underside of the laminate substrate when the dual-sided module having the assembly is mounted on a circuit board.

25. A packaged module comprising:
a packaging substrate having a first side and a second side;
an array of conductive assemblies implemented on the second side of the packaging substrate, each conductive assembly including a conductive pad, a conductive post including a first portion having a lateral dimension formed over the conductive pad and a second portion having a lateral dimension formed over the first portion, the lateral dimension of the first portion less than the lateral dimension of the second portion;
a dielectric layer implemented on the second side of the packaging substrate to cover the conductive pads and surround the first portion of each conductive post; and
a component mounted over the second side of the packaging substrate and within an inner region defined by the array of conductive assemblies, such that the packaged module is capable of being mounted on a circuit board with the conductive posts.

26. The packaged module of claim 25 further comprising one or more components mounted over the first side of the packaging substrate.

27. The packaged module of claim 26 further comprising an overmold formed over the first side of the packaging substrate to encapsulate the one or more components.

28. The packaged module of claim 25 further comprising an overmold formed over the second side of the packaging substrate to encapsulate the component mounted thereto and to surround some or all of a side wall of each conductive post.

29. A wireless device comprising:
an antenna; and
a radio-frequency circuit configured to operate with the antenna, at least some of the radio-frequency circuit implemented in a packaged module including a packaging substrate having a first side and a second side, and an array of conductive assemblies implemented on the second side of the packaging substrate, each conductive assembly including a conductive pad, a conductive post including a first portion having a lateral dimension formed over the conductive pad and a second portion having a lateral dimension formed over the first portion, the lateral dimension of the first portion less than the lateral dimension of the second portion, the packaged module further including a dielectric layer implemented on the second side of the packaging substrate to cover the conductive pads and surround the first portion of each conductive post, the packaged module further including a component mounted over the second side of the packaging substrate and within an inner region defined by the array of conductive assemblies, such that the packaged module is capable of being mounted on a circuit board with the conductive posts.

30. A method for fabricating an assembly for a packaged module, the method comprising:
forming or providing a packaging substrate having a surface;
implementing an array of conductive pads over the surface;
forming a dielectric layer over the array of conductive pads;
forming an opening having a lateral dimension through the dielectric layer over each of the conductive pads; and
forming a conductive post over each conductive pad, such that the conductive post includes a first portion that substantially fills the respective opening, the conductive post further including a second portion having a lateral dimension formed over the first position, the lateral dimension of the opening less than the lateral dimension of the second portion.

31. The method of claim 30 wherein the forming of the array of conductive pads includes forming a conductive seed layer on the surface, patterning the conductive pads on the conductive seed layer, and removing portions of the conductive seed layer not covered by the conductive pads.

32. The method of claim 31 wherein the conductive seed layer includes a copper seed layer, and each conductive pad includes copper.

33. The method of claim 31 wherein the patterning of the conductive pads includes a modified semi-additive process (mSAP), and the removing of the portions of the conductive seed layer includes an etching process.

34. The method of claim 30 wherein the forming of the conductive posts includes forming a conductive seed layer to cover the dielectric layer, the openings, and a surface of each conductive pad exposed by the respective opening.

35. The method of claim 34 wherein the forming of the conductive seed layer includes forming a copper seed layer with an electroless copper (E'less Cu) plating process.

36. The method of claim 30 wherein the forming of the conductive posts includes forming a dry fill layer over the dielectric layer and the openings of the dielectric layer, forming an opening through the dry fill layer over each conductive pad, forming the conductive post to fill some or all of the respective opening of dry fill layer, and removing the dry fill layer after the formation of the conductive posts.

37. The method of claim 36 wherein the forming of each conductive post includes a copper plating process, and the removing of the dry fill layer includes an etching process.

38. The method of claim 36 further comprising forming a protective coating to cover exposed surfaces of the conductive posts.

39. The method of claim 38 wherein the protective coating includes a solderability preservative coating.

40. The method of claim 39 wherein the solderability preservative coating includes an organic solderability preservative (OSP) coating or a nickel/gold (Ni/Au) coating.

41. A method for fabricating a packaged module, the method comprising:
forming or providing an assembly that includes a packaging substrate having a first side and a second side, an array of conductive pads implemented on the second side, a conductive post formed over each conductive pad such that the conductive post includes a first portion having a lateral dimension formed over the conductive pad and a second portion having a lateral dimension formed over the first portion, and such that the lateral dimension of the first portion is less than the lateral dimension of the second portion, and a dielectric layer implemented over the second side to cover the conductive pads and surround the first portion of each conductive post; and
mounting a component over the second side of the packaging substrate and within an inner region defined by the array of conductive pads, such that the packaged module is capable of being mounted on a circuit board with the conductive posts.

42. The method of claim 41 further comprising mounting one or more components over the first side of the packaging substrate.

43. The method of claim 42 further comprising forming an overmold over the first side of the packaging substrate to encapsulate the one or more components.

44. The method of claim 41 further comprising forming an overmold over the second side of the packaging substrate to encapsulate the component mounted thereto and to surround some or all of a side wall of each conductive post.
